(19) United States
(12) Patent Application Publication
(10) Pub. No.: US 2017/0269219 A1
(43) Pub. Date: Sep. 21, 2017

(54) Antenna Monitoring Device and Location-Information Notification Device

(71) Applicant: KYB Corporation, Tokyo (JP)

(72) Inventors: Hideo Matsushima, Tokyo (JP); Tomoyuki Kawano, Tokyo (JP)

(21) Appl. No.: 15/507,129

(22) PCT Filed: Aug. 19, 2015
(86) PCT No.: PCT/JP2015/073194

§ 371 Date: Feb. 27, 2017

(30) Foreign Application Priority Data
Aug. 25, 2014 (JP) 2014-170248

(51) Int. Cl. G01S 19/23; G01R 29/10; G01S 19/36; G01R 31/02

(52) U.S. Cl. CPC G01S 19/23; G01R 31/025; G01R 29/10; G01S 19/36

(57) ABSTRACT

To accurately monitor the status of an antenna even when characteristics of the antenna chronologically change, the antenna is replaced, and the like.

This device 1 includes a GPS receiver 11, a GPS antenna 12, a modem 12 for transmitting location information of a vehicle that is received by the GPS receiver 11, an antenna current source 13 and a current/voltage conversion unit 14 that detect the status of the GPS antenna 12, a storage unit 16 that rewritably stores a threshold for the status of the GPS antenna 12, and a control unit 18 that determines the status of the GPS antenna 12 and rewrites the threshold stored in the storage unit 12.

### TECHNICAL FIELD

The present invention relates to an antenna monitoring device for monitoring a breakdown of an antenna, such as a short circuit and a disconnection, and to a location-information notification device having such a monitoring function.

### BACKGROUND ART

Location information of construction machines such as a hydraulic shovel is grasped by a center device that manages those construction machines in preparation for stealing or the like. For example, the construction machines each have a communication function of transmitting location information and continuously notify the management center device of the location information. The location information is obtained in the management center device by a GPS (Global Positioning System).

In order to continuously perform notification of such location information, a monitoring function for maintaining a function related to the GPS for a long time is also necessary to be provided. For example, it is conceived that a monitoring device is provided to issue an alarm indicating that an antenna connected to a GPS receiver suffers a breakdown due to a short circuit, a disconnection, or the like.

Patent Document 1 discloses a technology that provides a direct current to a cable jacket and an antenna via a resistor, compares a voltage of the cable jacket and a particular preset threshold voltage (voltage of direct-current power source) by a comparator, and detects a disconnection when the voltage of the cable jacket reaches the threshold voltage.

Patent Document 1: Japanese Patent Application Laid-open No. 2007-318473

### SUMMARY OF INVENTION

### Problem to be Solved by the Invention

Characteristics of an antenna chronologically change and may differ when the antenna is replaced with another one, for example. In contrast to this, in the detection technology disclosed in Patent Document 1, the threshold voltage is fixed. As a result, a false detection possibly occurs due to the chronological change in characteristics of the antenna or the replacement of the antenna.

In view of the circumstances as described above, it is an object of the present invention to provide an antenna monitoring device and a location-information notification device that are capable of accurately monitoring the status of an antenna even when characteristics of the antenna chronologically change, the antenna is replaced, and the like.

### Means for Solving the Problem

In order to achieve the object described above, according to one embodiment of the present invention, there is provided an antenna monitoring device including: a detection unit that detects a status of an antenna; a storage unit that rewritably stores a threshold for the status of the antenna; a determination unit that compares a detection result by the detection unit and the threshold stored in the storage unit and determines the status of the antenna on the basis of a comparison result; and a rewrite unit that rewrites the threshold stored in the storage unit.

In the antenna monitoring device according to one embodiment of the present invention, the threshold for the status of the antenna is rewritable. Thus, it is possible to accurately monitor the status of the antenna even when characteristics of the antenna chronologically change, the antenna is replaced, and the like.

The antenna monitoring device according to one embodiment of the present invention may further include an external interface unit that is connected with a terminal device or a communication line for inputting a threshold for rewrite by the rewrite unit.

This makes it possible to easily rewrite the threshold for the status of the antenna with use of an external terminal device.

The antenna monitoring device according to one embodiment of the present invention may further include an alarm unit that issues an alarm according to a determination result by the determination unit,

This makes it possible to notify a user of a time for replacement of the antenna.

In the antenna monitoring device according to one embodiment of the present invention, the storage unit may rewritably store a threshold at which the antenna is short-circuited or a threshold at which the antenna is disconnected, and the determination unit may determine the status of the antenna on the basis of the comparison result.

This eliminates an erroneous determination that the antenna is short-circuited or disconnected or the antenna has a high possibility of causing a short circuit or a disconnection.

In the antenna monitoring device according to one embodiment of the present invention, the storage unit may rewritably store a threshold indicating whether the antenna is getting close to short-circuited or a threshold indicating whether the antenna is getting close to disconnected, and the determination unit may determine whether the antenna is getting close to short-circuited or the antenna is getting close to disconnected, on the basis of the comparison result.

This enables the user to prepare for a short circuit or a disconnection well in advance. Further, the alarm as described above becomes a trigger for the user to rewrite the threshold data. This can more reliably prevent the antenna from being erroneously determined to be short-circuited or disconnected.

According to one embodiment of the present invention, there is provided a vehicle-location-information notification device, which is mounted in a vehicle and notifies location information of the vehicle, the vehicle-location-information notification device including: a GPS (Global Positioning System) receiver and a GPS antenna for acquiring the location information of the vehicle; a communication unit that transmits the location information of the vehicle, the location information being received by the GPS receiver; a detection unit that detects a status of the GPS antenna; a storage unit that rewritably stores a threshold for the status of the GPS antenna; a determination unit that compares a detection result by the detection unit and the threshold stored in the storage unit and determines the status of the GPS antenna on the basis of a comparison result; and a rewrite unit that rewrites the threshold stored in the storage unit.

In the vehicle-location-information notification device according to one embodiment of the present invention, the threshold for the status of the GPS antenna is rewritable. Thus, it is possible to accurately monitor the status of the GPS antenna even when characteristics of the GPS antenna chronologically change, the GPS antenna is replaced, and the like.

According to one embodiment of the present invention, there is provided a program causing a computer to execute: detecting a status of an antenna; rewritably storing a threshold for the status of the antenna in a storage unit; comparing the detection result and the threshold stored in the storage unit and determining the status of the antenna on the basis of a comparison result; and rewriting the threshold stored in the storage unit.

In the program according to one embodiment of the present invention, the threshold for the status of the antenna is rewritable. Thus, it is possible to accurately monitor the status of the antenna even when characteristics of the antenna chronologically change, the antenna is replaced, and the like.

### Effects of the Invention

According to the present invention, it is possible to accurately monitor the status of an antenna even when characteristics of the antenna chronologically change, the antenna is replaced, and the like.

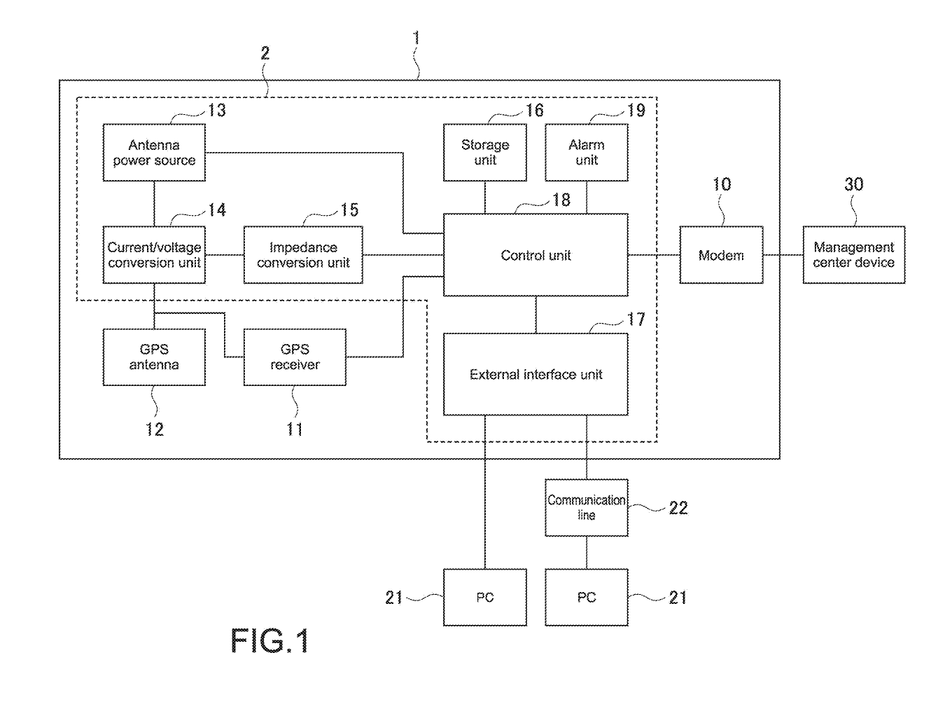

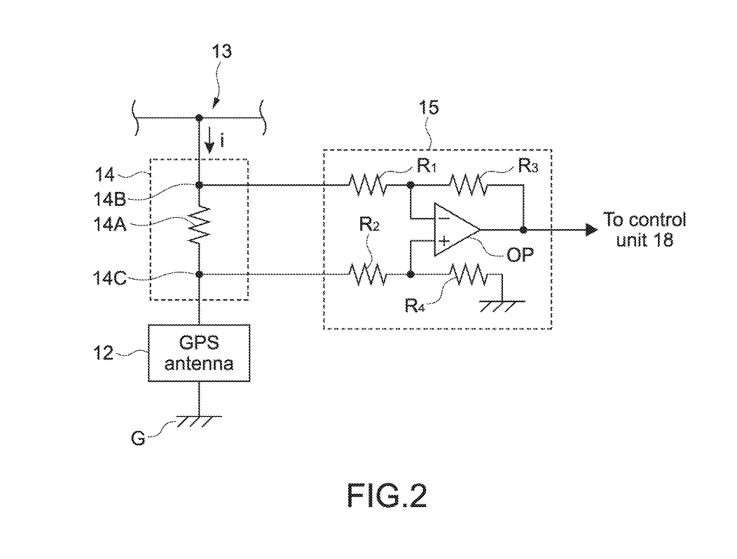

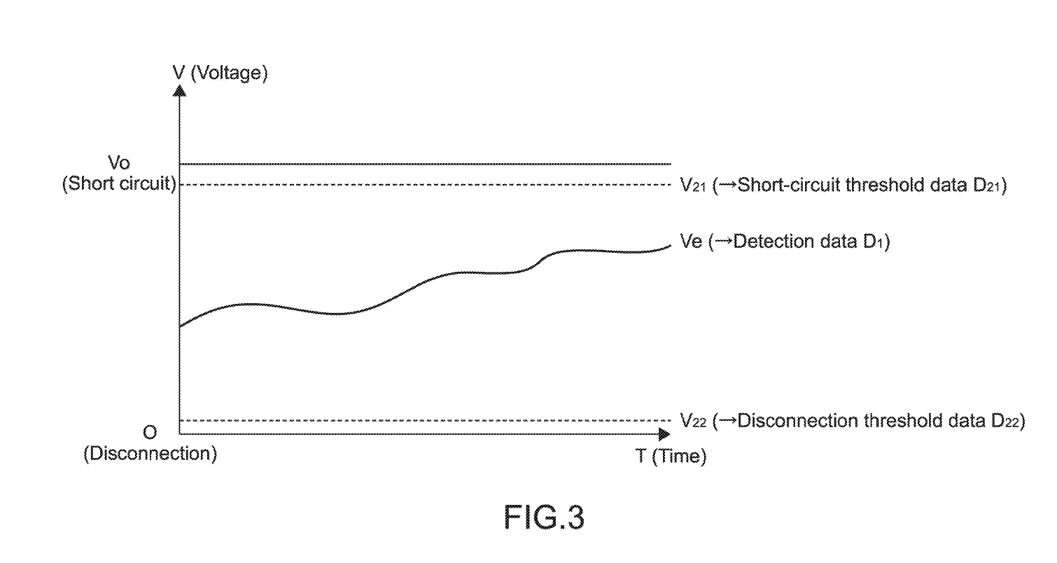

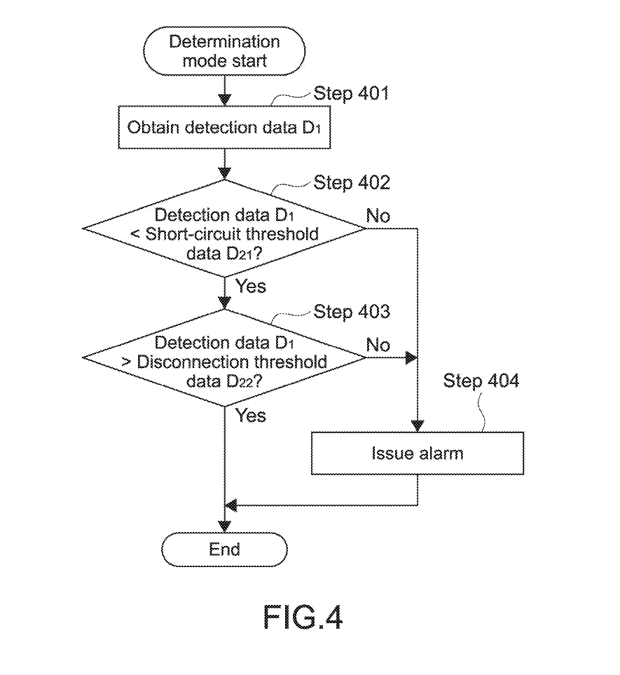

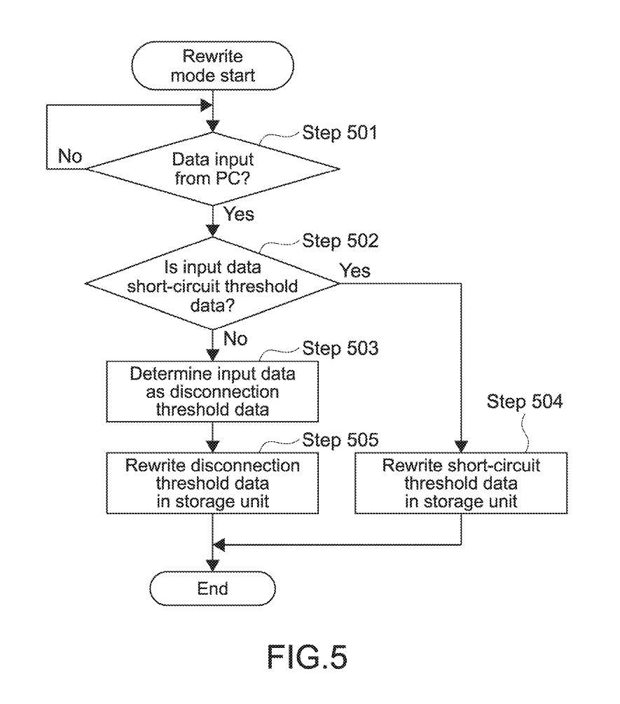

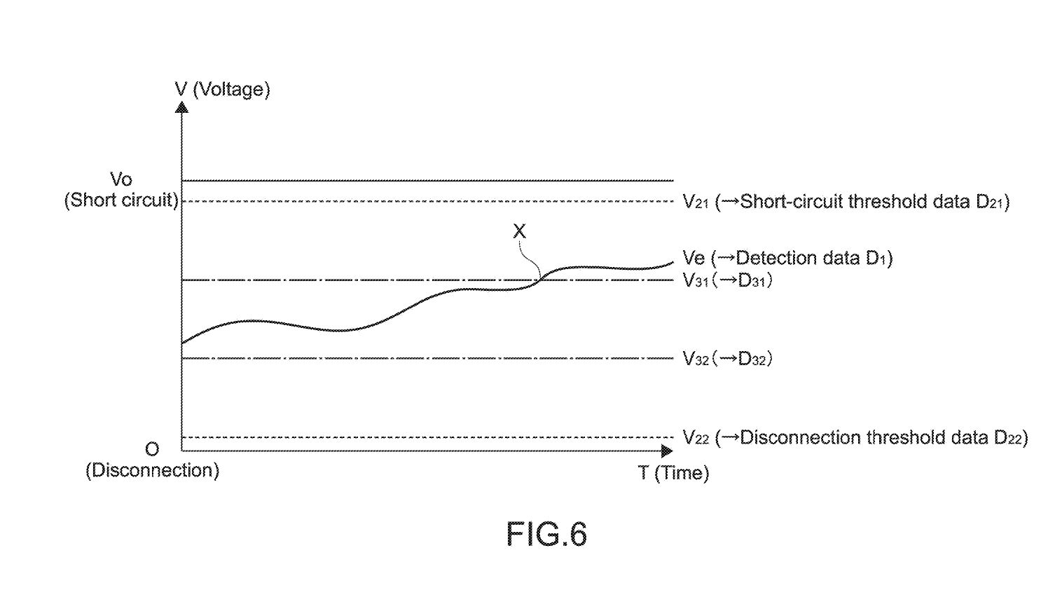

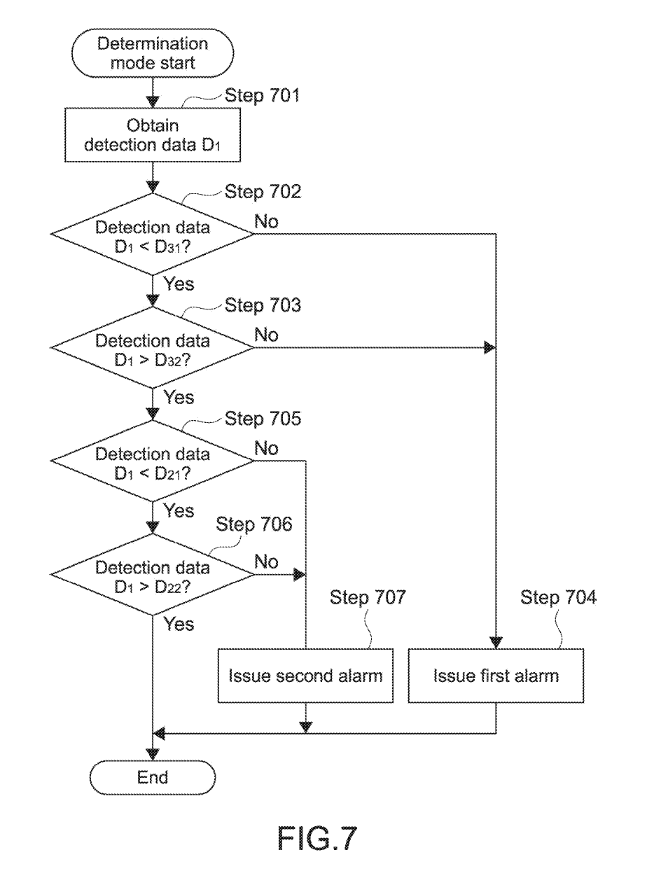

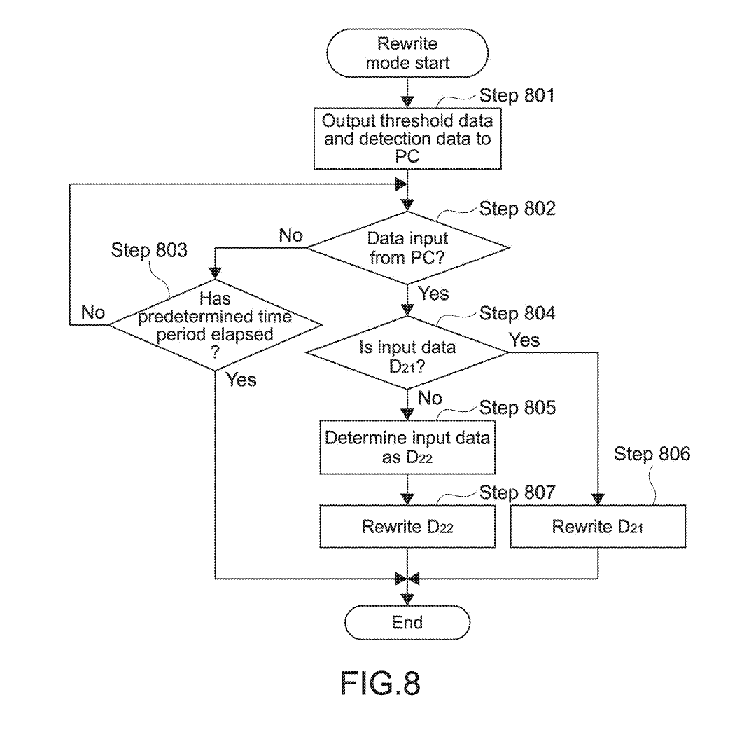

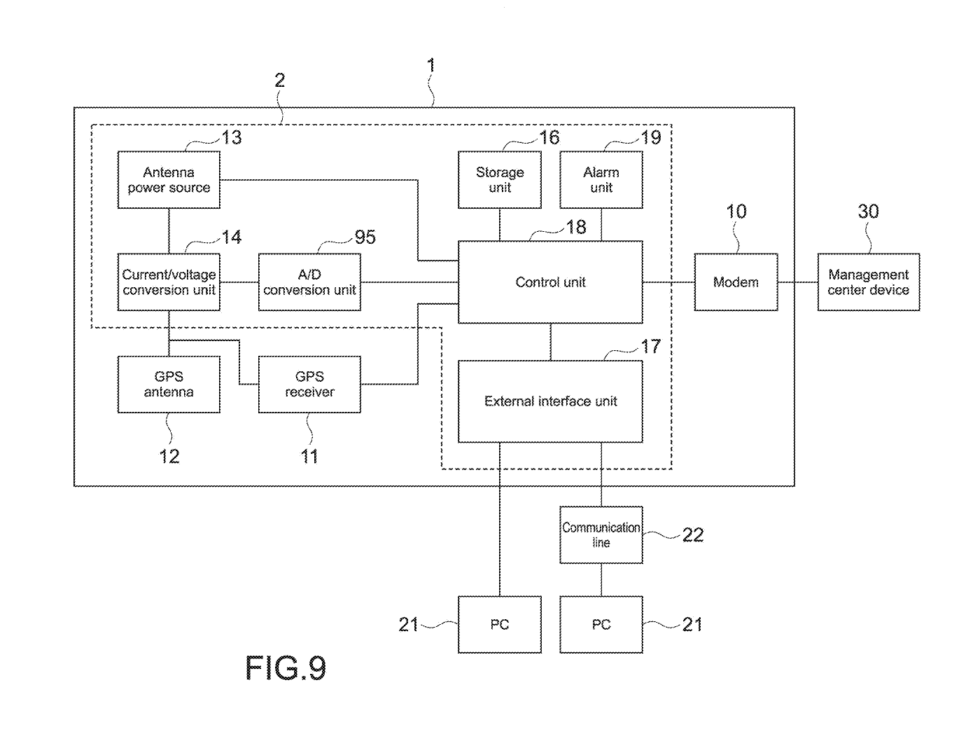

### BRIEF DESCRIPTION OF DRAWINGS

[FIG. 1] FIG. 1 is a block diagram showing a configuration of a vehicle-location-information notification device according to a first embodiment of the present invention.

[FIG. 2] FIG. 2 is a diagram showing a configuration example of a current/voltage conversion unit and an impedance conversion unit shown in FIG. 1.

[FIG. 3] FIG. 3 is a graph for describing a chronological change in characteristics of an antenna, a short circuit, a disconnection, a threshold, and the like according to the first embodiment of the present invention.

[FIG. 4] FIG. 4 is a flowchart showing an example of an operation in a mode for determining the status of a GPS antenna according to the first embodiment of the present invention.

[FIG. 5] FIG. 5 is a flowchart showing an example of an operation in a mode for rewriting threshold data according to the first embodiment of the present invention.

[FIG. 6] FIG. 6 is a graph for describing a chronological change in characteristics of an antenna, a short circuit, a disconnection, a threshold, and the like according to a second embodiment of the present invention.

[FIG. 7] FIG. 7 is a flowchart showing an example of an operation in a mode for determining the status of a GPS antenna according to the second embodiment of the present invention.

[FIG. 8] FIG. 8 is a flowchart showing an example of an operation in a mode for rewriting threshold data according to a third embodiment of the present invention.

[FIG. 9] FIG. 9 is a block diagram showing a configuration of a vehicle-location-information notification device according to a fourth embodiment of the present invention.

### MODE(S) FOR CARRYING OUT THE INVENTION

Hereinafter, embodiments of the present invention will be described with reference to the drawings.

### First Embodiment

FIG. 1 is a block diagram showing a configuration of a vehicle-location-information notification device according to a first embodiment of the present invention.

As shown in FIG. 1, this vehicle-location-information notification device 1 is typically mounted to a construction machine such as a hydraulic shovel, and notifies a management center device 30 of location information of the vehicle, the management center device 30 being in a remote location.

The vehicle-location-information notification device 1 includes a modem 10, a GPS (Global Positioning System) receiver 11, a GPS antenna 12, an antenna current source 13, a current/voltage conversion unit 14, an impedance conversion unit 15, a storage unit 16, an external interface unit 17, a control unit 18, and an alarm unit 19.

The GPS receiver 11 and the GPS antenna 12 obtain location information of the vehicle by using the GPS, the vehicle being equipped with the vehicle-location-information notification device 1.

The location information of the vehicle is transmitted to the management center device 30, for example, periodically under control of the control unit 18 via the modem 10 serving as a communication unit. The vehicle-location-information notification device 1 basically has such a function. The vehicle-location-information notification device 1 according to this embodiment is additionally provided with a function as an antenna monitoring device 2. The antenna monitoring device 2 is constituted of a detection unit including the antenna current source 13 and the current/voltage conversion unit 14, the impedance conversion unit 15, the storage unit 16, the external interface unit 17, the alarm unit 19, and the control unit 18 that controls those units.

Here, the antenna current source 13 applies a direct-current constant voltage of about 5 V or 3 V to the GPS antenna 12, and provides a current for determining the status of the GPS antenna 12 to the GPS antenna 12. The GPS antenna 12 includes a coaxial cable, a connector, and the like in addition to an antenna main body.

The current/voltage conversion unit 14 is disposed between the GPS antenna 12 and the antenna current source 13 and performs conversion into a voltage having a value based on the current flowing from the antenna current source 13 to the GPS antenna 12.

The impedance conversion unit 15 adjusts impedance conversion between the current/voltage conversion unit 14 and the control unit 18.

The storage unit 16 rewritably stores data (threshold data) that serves as a predetermined threshold based on the status of the GPS antenna 12. The storage unit 16 is constituted of a memory element in which data is rewritable.

The external interface unit 17 is an interface for exchanging data with the outside. A user causes a personal computer (PC) 21 serving as a terminal device connected to the external interface unit 17 or a PC 21 connected to the external interface unit 17 via a communication line (wireless or wired) 22 to exchange data with the vehicle-location-information notification device 1. This enables the user to rewrite threshold data stored in the storage unit 16 and to recognize a determination result by a determination unit, which will be described later, with use of the PC 21. It should be noted that a smartphone, a mobile phone, and the like can be used as the terminal device, in addition to the PC.

The control unit 18 converts the voltage, which is converted by the impedance conversion unit 15 and serves as an analog signal, into digital data based on a value of the voltage. Further, on the basis of this data (detection data) and the threshold data stored in the storage unit 16, the control unit 18 determines the status of the GPS antenna 12. Furthermore, the control unit 18 controls the whole of the vehicle-location-information notification device 1, inclusive of the above-mentioned rewrite of the threshold data. In other words, the control unit 18 has a function as a determination unit and a rewrite unit.

The alarm unit 19 issues a predetermined alarm according to the status of the GPS antenna 12, for example, when there is a possibility that a short circuit or a disconnection occurs. The alarm of the alarm unit 19 can be issued by, for example, ringing of an alarm sound or indication of an alarm.

FIG. 2 is a diagram showing a configuration example of the current/voltage conversion unit 14 and impedance conversion unit 15 described above.

As shown in the figure, a resistor 14A of the current/voltage conversion unit 14 and the GPS antenna 12 that can be assumed as a resistor are connected to each other in series between the antenna current source 13 and the ground G. The current/voltage conversion unit 14 includes connection terminals 14B and 14C at both ends of the resistor 14A. A potential difference between the connection terminals 14B and 14C is a voltage based on the value of the current flowing from the antenna current source 13 to the GPS antenna 12. For example, as the current flowing from the antenna current source 13 to the GPS antenna 12 increases, the voltage increases, and as the current flowing from the antenna current source 13 to the GPS antenna 12 decreases, the voltage decreases.

The impedance conversion unit 15 is constituted of a differential amplifier including resistors R1 to R4 and an operational amplifier OP, for example.

Here, when the voltage of the antenna current source 13 is denoted by Vₒ, a resistance of the GPS antenna 12 is denoted by R_{g}, and the resistance 14A of the current/voltage conversion unit 14 is denoted by R_{c}, a voltage Vₑ applied to the resistor 14A of the current/voltage conversion unit 14 is as follows.

Vₑ=Vₒ×R_{c}/(R_{c}+R_{g})

Here, when the GPS antenna 12 is short-circuited, R_{g} becomes 0 Ω, and Vₑ=Vₒ. Meanwhile, when the GPS antenna 12 is disconnected, R_{g} becomes ∞ Ω, and Vₑ=0 V.

Even when the GPS antenna 12 is not short-circuited or disconnected, R_{g} changes due to a chronological change in characteristics thereof, such as degradation. Thus, Vₑ chronologically changes as shown in FIG. 3, for example. The Vₑ passes through the impedance conversion unit 15 and is subjected to the digital conversion in the control unit 18, and thus detection data D1 is obtained.

The data serving as the threshold stored in the storage unit 16 is digital data, which corresponds to a predetermined threshold based on the status (short circuit, disconnection, etc.) of the GPS antenna 12. As a typical example, the digital conversion is performed on a voltage V21, which is slightly smaller than Vₒ at which the GPS antenna 12 is short-circuited, to obtain short-circuit threshold data D21, and the digital conversion is performed on a voltage V22, which is slightly larger than 0 V at which the GPS antenna 12 is disconnected, to obtain disconnection threshold data D22. The short-circuit threshold data D21 and the disconnection threshold data D22 are stored as threshold data in the storage unit 16. As a matter of course, it may be substantively possible to set V21 to be Vₒ and V22 to be 0. Further, in this embodiment, the threshold data is short-circuit threshold data for a short circuit and disconnection threshold data for a disconnection, but may be any one of them.

FIG. 4 is a flowchart showing an example of an operation in a mode for determining the status of the GPS antenna 12. This determination mode may be manually set by the user or set with a tinier at predetermined time intervals.

When being set to the determination mode, first, the control unit 18 inputs the voltage Vₑ, which is converted by the current/voltage conversion unit 14, through the impedance conversion unit 15, and converts the voltage Vₑ into digital data, to obtain detection data D1 (Step 401).

Next, the control unit 18 reads the short-circuit threshold data D21 among the threshold data stored in the storage unit 16 and determines whether the data D1 is smaller than the short-circuit threshold data D21 (Step 402).

When the detection data D1 is smaller than the short-circuit threshold data D21 (Yes in Step 402), that is, when the GPS antenna 12 has a low possibility of causing a short circuit, the control unit 18 reads the disconnection threshold data D22 among the threshold data stored in the storage unit 16 and determines whether the data D1 is larger than the disconnection threshold data D22 (Step 403).

When the detection data D1 is larger than the disconnection threshold data D22 (Yes in Step 403), that is, when the GPS antenna 12 has a low possibility of causing a disconnection, the control unit 18 regards the status of the GPS antenna 12 as normal and terminates the determination mode.

Meanwhile, in the case of No in Step 402, that is, when the detection data D1 is larger than the short-circuit threshold data D21, the control unit 18 regards the GPS antenna 12 as having a high possibility of causing a short circuit. Alternatively, in the case of No in Step 403, that is, when the detection data D1 is smaller than the disconnection threshold data D22, the control unit 18 regards the GPS antenna 12 as having a high possibility of causing a disconnection. Thus, the control unit 18 issues an alarm from the alarm unit 19 (Step 404).

It should be noted that before the determination mode is terminated, the PC 21 may be notified of a determination result by the determination unit in a wired or wireless manner. This enables the user to recognize the presence or absence of an abnormality of the antenna 12.

FIG. 5 is a flowchart showing an example of an operation in a mode for rewriting the threshold data stored in the storage unit 16. The rewrite mode may be set when the PC 21 is connected to the external interface unit 17 or when the PC 21 sets the rewrite mode. Alternatively, the rewrite mode may be set when the PC 21 sets the rewrite mode via the communication line (wireless or wired) 22.

When being set to the rewrite mode, the control unit 18 waits for an input of rewrite data from the PC 21 via the external interface unit 17 (Step 501).

Next, when the rewrite data is input from the PC 21, the control unit 18 determines whether the data is the short-circuit threshold data D21 among the threshold data (Step 502).

Further, when the data input from the PC 21 is not the short-circuit threshold data D21 among the threshold data (No in Step 502), the control unit 18 determines that the data is the disconnection threshold data D22 (Step 503).

The above determination on the short-circuit threshold data D21 or the disconnection threshold data D22 may be performed by, for example, providing an identification flag to the header of the data or may be achieved by other well-known technologies.

When the data input from the PC 21 is the short-circuit threshold data D21 among the threshold data, the control unit 18 uses that short-circuit threshold data D21 to rewrite the short-circuit threshold data D21 stored until then in the storage unit 16 (Step 504). Further, when the data input from the PC 21 is the disconnection threshold data D22 among the threshold data, the control unit 18 uses that disconnection threshold data D22 to rewrite the disconnection threshold data D22 stored until then in the storage unit 16 (Step 505).

By the rewrite mode described above, the user can rewrite, with use of the PC 21, the threshold data (the short-circuit threshold data D21 and the disconnection threshold data D22 stored in the storage unit 16), which are to be thresholds for issuing an alarm for a short circuit, a disconnection, or the like of the GPS antenna 12 and correspond to the V21 and the V22 indicated by dotted lines in FIG. 3.

As shown in FIG. 3, since the resistance R_{g} of the GPS antenna 12 changes due to a chronological change, the current flowing from the antenna current source 13 to the GPS antenna 12 via the current/voltage conversion unit 14 also changes. Therefore, the voltage Vₑ converted by the current/voltage conversion unit 14 also changes. When the detection data D1 exceeds the threshold (D21) or becomes equal to or smaller than the threshold (D22) by the change in voltage Vₑ, the control unit 18 may erroneously determine that the GPS antenna 12 is short-circuited or disconnected or has a high possibility of causing a short circuit or a disconnection. In the vehicle-location-information notification device 1 according to this embodiment, for example, when a predetermined time period has elapsed, the user rewrites the threshold data (short-circuit threshold data D21, disconnection threshold data D22) stored in the storage unit 16 in consideration of a change in resistance R_{g} of the GPS antenna 12. This can prevent the GPS antenna 12 from being erroneously determined to be short-circuited or disconnected or to have a high possibility of causing a short circuit or a disconnection.

Further, the resistance R_{g} of the GPS antenna 12 may change also when the GPS antenna 12 is replaced with another one. In this case as well, the current flowing from the antenna current source 13 to the current/voltage conversion unit 14 and the GPS antenna 12 changes, and there is a possibility that the GPS antenna 12 is erroneously determined to be short-circuited or disconnected or to have a high possibility of causing a short circuit or a disconnection. In such a case as well, the threshold data stored in the storage unit 16 is rewritten with threshold data corresponding to a new GPS antenna 12, and the erroneous determination can thus be prevented.

In other words, the vehicle-location-information notification device 1 according to this embodiment is configured such that the threshold used for determination on the status of the GPS antenna 12 can be rewritten by the user. Thus, the GPS antenna 12 is not erroneously determined to be short-circuited or disconnected or to have a high possibility of causing a short circuit or a disconnection due to a chronological change in characteristics of the GPS antenna 12 or replacement thereof. Therefore, for example, the user does not erroneously replace a normal GPS antenna 12.

It should be noted that the threshold may be automatically set according to the voltage of the antenna current source 13. For example, the following settings are made: for the antenna current source 13 of 12 V, V21=11 V; and for the antenna current source 13 of 24 V, V21=23 V. Thus, an appropriate threshold can be easily set according to the specifications of the antenna current source 13.

### Second Embodiment

Next, a second embodiment of the present invention will be described.

In the embodiment described above, a short circuit or a disconnection of the GPS antenna 12 is determined. In this second embodiment, it is also determined whether the GPS antenna 12 is getting close to short-circuited and the GPS antenna 12 is getting close to disconnected.

A vehicle-location-information notification device 1 according to the second embodiment can have a configuration similar to the device configuration shown in FIG. 1, but the storage unit 16 and the control unit 18 are different from those described above in the following points.

Here, the storage unit 16 of the vehicle-location-information notification device 1 according to the second embodiment rewritably stores threshold data D31 and threshold data D32 as threshold data, in addition to the short-circuit threshold data D21 and the disconnection threshold data D22. The threshold data D31 indicates whether the GPS antenna 12 is getting close to short-circuited. The threshold data D32 indicates whether the GPS antenna 12 is getting close to disconnected.

As shown in FIG. 6, a predetermined value that is smaller than the short-circuit threshold data D21, for example, a value at which a short circuit is predicted several months later is set for the threshold data D31 indicating whether the GPS antenna 12 is getting close to short-circuited. Similarly, a value that is larger than the disconnection threshold data D22, for example, a value at which a disconnection is predicted several months later is set for the threshold data D32 indicating whether the GPS antenna 12 is getting close to disconnected.

FIG. 7 is a flowchart showing an example of an operation in a mode for determining the status of the GPS antenna 12 according to the second embodiment. This determination mode may also be manually set by the user or set with a timer at predetermined time intervals.

When being set to the determination mode, first, the control unit 18 inputs the voltage Yₑ, which is converted by the current/voltage conversion unit 14, through the impedance conversion unit 15, and converts the voltage Vₑ into digital data, to obtain detection data D1 (Step 701).

Next, the control unit 18 reads the threshold data D31 among the threshold data stored in the storage unit 16 and determines whether the data D1 is smaller than the threshold data D31 (Step 702).

When the detection data D1 is smaller than the threshold data D31 (Yes in Step 702), that is, when it is regarded that the GPS antenna 12 is not getting close to short-circuited, the control unit 18 reads the threshold data D32 among the threshold data stored in the storage unit 16 and determines whether the data D1 is larger than the threshold data D32 (Step 703).

In the case of No in Step 702 (for example, point X in FIG. 6) or in the case of No in Step 703, a first alarm is issued from the alarm unit 19. The first alarm is for notifying the user of the fact that the GPS antenna 12 is getting close to short-circuited or the GPS antenna 12 is getting close to disconnected (Step 704).

Meanwhile, in the case of Yes in Step 703, the control unit 18 reads the threshold data D21 among the threshold data stored in the storage unit 16 and determines whether the data D1 is smaller than the threshold data D21 (Step 705).

When the detection data D1 is smaller than the threshold data D21 (Yes in Step 705), that is, when it is regarded that the GPS antenna 12 has a low possibility of causing a short circuit, the control unit 18 determines whether the data D1 is larger than the disconnection threshold data D22 (Step 706).

When the detection data D1 is larger than the disconnection threshold data D22 (Yes in Step 706), that is, when it is regarded that the GPS antenna 12 has a low possibility of causing a disconnection, the control unit 18 regards the status of the GPS antenna 12 as normal and terminates the determination mode.

Meanwhile, in the case of No in Step 705, that is, when the detection data D1 is larger than the short-circuit threshold data D21, or in the case of No in Step 706, that is, when the detection data D1 is smaller than the disconnection threshold data D22, the control unit 18 issues a second alarm from the alarm unit 19 (Step 707). The second alarm desirably has a form different from the first alarm, for example, a different volume or pitch in the case where the alarm is sound.

Also in this this embodiment, the four pieces of threshold data D21, D22, D31, and D32 stored in the storage unit 16 are rewritable similarly to the first embodiment.

Therefore, also in the vehicle-location-information notification device 1 according to the second embodiment, the threshold data stored in the storage unit 16 can be rewritten. This can prevent the GPS antenna 12 from being erroneously determined to be short-circuited or disconnected or to have a high possibility of causing a short circuit or a disconnection. In addition, the threshold data D31 indicating whether the GPS antenna 12 is getting close to short-circuited and the threshold data D32 indicating whether the GPS antenna 12 is getting close to disconnected are further used as threshold data so as to notify the user of the fact that the GPS antenna 12 is getting close to short-circuited or that the GPS antenna 12 is getting close to disconnected. This enables the user to prepare for a short circuit or a disconnection well in advance. Further, the alarm as described above becomes a trigger for the user to rewrite the threshold data stored in the storage unit 16. This can more reliably prevent the GPS antenna 12 from being erroneously determined to be short-circuited or disconnected or to have a high possibility of causing a short circuit or a disconnection.

It should be noted that the four pieces of threshold data D21, D22, D31, and D32 are used in the second embodiment described above, but the present invention is not limited thereto. Other threshold data, for example, any one of the four pieces of threshold data or a combination thereof may also be used as a matter of course.

### Third Embodiment

Next, a third embodiment of the present invention will be described.

FIG. 8 is a flowchart showing an example of an operation in a mode for rewriting threshold data in the third embodiment.

When being set to the rewrite mode, the control unit 18 transmits detection data, threshold data, and a determination result by the determination unit to the PC 21 via the external interface unit 17 (Step 801). For example, the past detection data, threshold data, and determination results by the determination unit may be accumulated in the storage unit 18 and transmitted to the PC 21. This enables the data shown in FIG. 3 to be presented to the user in the PC 21, for example. Thus, the user can appropriately set new threshold data (rewrite data) in the PC 21 on the basis of those pieces of data.

Subsequently, the control unit 18 waits for an input of rewrite data from the PC 21 via the external interface unit 17 (Step 802). Here, when the rewrite data is not input from the PC 21 even after a predetermined time period has elapsed (Step 803), the rewrite mode is terminated.

Meanwhile, when the rewrite data is input from the PC 21, the control unit 18 determines whether the data is the short-circuit threshold data D21 among the threshold data (Step 804).

Further, when the data input from the PC 21 is not the short-circuit threshold data D21 among the threshold data (No in Step 804), the control unit 18 determines that the data is the disconnection threshold data D22 (Step 805).

When the data input from the PC 21 is the short-circuit threshold data D21, the control unit 18 uses that short-circuit threshold data D21 to rewrite the short-circuit threshold data D21 stored until then in the storage unit 16 (Step 806). Further, when the data input from the PC 21 is the disconnection threshold data D22, the control unit 18 uses that disconnection threshold data D22 to rewrite the disconnection threshold data D22 stored until then in the storage unit 16 (Step 807).

### Fourth Embodiment

Next, a fourth embodiment of the present invention will be described.

FIG. 9 is a block diagram showing a configuration of a vehicle-location-information notification device 1 according to a fourth embodiment of the present invention.

In the vehicle-location-information notification device 1 shown in FIG. 1, the impedance conversion unit 15 is disposed between the current/voltage conversion unit 14 and the control unit 18, and the control unit 18 performs A/D (analog/digital) conversion. In contrast to this, as shown in FIG. 9, the vehicle-location-information notification device 1 according to the fourth embodiment is configured such that an A/D (analog/digital) conversion unit 95 is provided instead of the impedance conversion unit 15, and the A/D conversion unit 95 performs A/D conversion and also has a function as an impedance conversion unit. This can reduce the processing load on the control unit 18 substantially without increasing the number of components.

The embodiments of the present invention have been described hereinbefore, but the present invention is not limited to the above embodiments and can be variously modified without departing from the gist of the present invention as a matter of course.

For example, in the embodiments described above, the example in which the antenna monitoring device is used for a vehicle-location-information notification device has been described, but the antenna monitoring device according to the present invention can also be similarly used for another device equipped with an antenna.

Further, the above embodiments have described the GPS antenna as an example of an antenna, but another antenna may be used as a matter of course.

### DESCRIPTION OF SYMBOLS

1 vehicle-location-information notification device

10 modem (communication unit)

11 GPS receiver

12 GPS antenna

13 antenna current source (detection unit)

14 current/voltage conversion unit (detection unit)

15 impedance conversion unit

16 storage unit

17 interface unit

18 control unit (determination unit, rewrite unit)

19 alarm unit

21 PC

22 communication line (wireless/wired)

30 management center device

95 A/D conversion unit

D1 detection data

D21, D22, D31, D32 threshold data

1. An antenna monitoring device, comprising:
a detection unit that detects a status of an antenna;
a storage unit that rewritably stores a threshold for the status of the antenna;
a determination unit that compares a detection result by the detection unit and the threshold stored in the storage unit and determines the status of the antenna on the basis of a comparison result; and
a rewrite unit that rewrites the threshold stored in the storage unit.

2. The antenna monitoring device according to claim 1, further comprising
an external interface unit that is connected with a terminal device or a communication line for inputting a threshold for rewrite by the rewrite unit.

3. The antenna monitoring device according to claim 1, further comprising
an alarm unit that issues an alarm according to a determination result by the determination unit.

4. The antenna monitoring device according to claim 1, wherein
the storage unit rewritably stores a threshold at which the antenna is short-circuited and a threshold at which the antenna is disconnected, and
the determination unit determines the status of the antenna on the basis of the comparison result.

5. The antenna monitoring device according to claim 1, wherein
the storage unit rewritably stores a threshold at which the antenna is short-circuited, a threshold indicating whether the antenna is getting close to short-circuited or rewritably stores a threshold at which the antenna is disconnected, and a threshold indicating whether the antenna is getting close to disconnected, and
the determination unit determines whether the antenna is short-circuited and whether the antenna is getting close to short-circuited, or determines whether the antenna is disconnected and whether the antenna is getting close to disconnected, on the basis of the comparison result.

6. The antenna monitoring device according to claim 2, wherein the threshold stored in the storage unit is output to an outside via the external interface unit.

7. The antenna monitoring device according to claim 2, wherein
the detection result by the detection unit is output to an outside via the external interface unit.

8. A vehicle-location-information notification device, which is mounted in a vehicle and notifies location information of the vehicle, the vehicle-location-information notification device comprising:
a GPS (Global Positioning System) receiver and a GPS antenna for acquiring the location information of the vehicle;
a communication unit that transmits the location information of the vehicle, the location information being received by the GPS receiver;
a detection unit that detects a status of the GPS antenna;
a storage unit that rewritably stores a threshold for the status of the GPS antenna;
a determination unit that compares a detection result by the detection unit and the threshold stored in the storage unit and determines the status of the GPS antenna on the basis of a comparison result; and
a rewrite unit that rewrites the threshold stored in the storage unit.
